(19) United States
(12) Patent Application Publication
(10) Pub. No.: US 2012/0194284 A1
(43) Pub. Date: Aug. 2, 2012

(54) OSCILLATION CIRCUIT HAVING SHIELD WIRE, AND ELECTRONIC APPARATUS

(76) Inventor: Hiroyuki Souma, Chiba-shi (JP)

(21) Appl. No.: 13/357,770

(22) Filed: Jan. 25, 2012

(30) Foreign Application Priority Data
Jan. 28, 2011 (JP) 2011-017052

(51) Int. Cl. H03B 5/32

(52) U.S. Cl. 331/158

(57) ABSTRACT

There is provided an oscillation circuit including a crystal vibrator that is connected between input and output terminals of a CMOS inverter making up the oscillation circuit; an input wiring line that includes a crystal vibrator-side input terminal connected to an input terminal pad of the CMOS inverter; an output wiring line that includes a crystal vibrator-side output terminal connected to an output terminal pad of the CMOS inverter; a ground power source wiring line that includes a crystal vibrator-side ground power source terminal; and a capacitative element that is connected between the input wiring line and the ground power source wiring line, and between the output wiring line and the ground power source wiring line, wherein the ground power source wiring line is disposed at least a part of between the input wiring line and the output wiring line.

### RELATED APPLICATIONS

This application claims priority under 35 U.S.C. §119 to Japanese Patent Application No. 2011-017052 filed on Jan. 28, 2011, the entire content of which is hereby incorporated by reference.

### BACKGROUND OF THE INVENTION

1. Field of the Invention

The present invention relates to a method of realizing a low power-consumption crystal oscillation circuit, and more particularly, to a method of realizing a reduction in a load capacitance making up a crystal oscillation circuit.

2. Description of the Related Art

In regard to a portable apparatus such as a timepiece or a cellular phone, from a demand for long-term operation of the apparatus without charging and a reduction in the charging frequency of a mounted battery, a reduction in a driving power of an oscillation circuit to which a piezoelectric element such as a crystal vibrator or the like, which is used for the apparatus, is assembled, and ultra-low power-consumption when the oscillation circuit is in a standby state (in a state where the oscillation circuit has been oscillated and an unloaded state) are further demanded.

FIG. 12 shows a typical oscillation circuit using a crystal vibrator as a piezoelectric vibrator, and the oscillation circuit includes a CMOS inverter IV01 that is an inverting amplifier, a crystal vibrator X2 connected between an input terminal XCIN and an output terminal XCOUT of the CMOS inverter IV01, a capacitative element that is connected between the input terminal XCIN of the CMOS inverter IV01 and a power source terminal of a ground potential Vss and makes up a load capacitance Cg, and a capacitative element that is connected between the output terminal XCOUT of the CMOS inverter IV01 and the power source terminal of the ground potential Vss and makes up a load capacitance Cd.

In addition, the CMOS inverter IV01 includes, a PMOS transistor PM11 that is serially connected between a first power source terminal with which a power source voltage Vdd is shared and a second power source terminal to which a ground potential is supplied, a CMOS inverter including an NMOS transistor NM11, and a feedback resistor Rf.

Driving current adjusting resistor elements r1 and r2 that restrict a driving current for exciting the crystal vibrator X2 are connected between a source of the PMOS transistor PM11 of the CMOS inverter IV01 and the first power source terminal, and between the NMOS transistor NM11 of the CMOS inverter IV02 and the second power source terminal.

Recently, in an oscillation circuit that is mounted in a portable apparatus or the like, low power consumption is requested, but as a result thereof, it is necessary to decrease a driving current of a crystal vibrator in the oscillation circuit. Therefore, a mutual conductance Gm of a CMOS inverter in the oscillation circuit is made to be small. However, when the mutual conductance Gm is made to be small, an oscillation margin M of the oscillation circuit may be decreased.

The oscillation margin M of the oscillation circuit is given by the following equation.

M=|−Gm|/{(ω²Cg·Cd)*(1/R1(max))}=+RL/R1(max)

Here, ω represents an angular frequency of an oscillation frequency, RL represents a negative resistance, R1 (max) represents a maximum value of an effective resistance R1 of the crystal vibrator, and a value of 5 or more is requested for the oscillation margin M.

The effective resistance R1 of the crystal vibrator is a value determined from a request for miniaturization of the crystal vibrator, such that it is difficult to make the effective resistance R1 too small. Therefore, to maintain the oscillation margin M of the oscillation circuit even when the mutual conductance Gm is made to be small, it is understood that it is preferable to decrease a load capacitance Cg and/or Cd of a condenser making up a load capacitance that is externally attached to the CMOS inverter. Therefore, to realize this, it is requested that the crystal vibrator of the oscillation circuit has a load capacitance CL that is appropriate for specification of low power consumption requested with respect to an IC of a microcomputer or the like to which the oscillation circuit is assembled. That is, the present applicant has already suggested decreasing the load capacitance CL, that is, the lowering of CL (3 to 5 pF) with respect to 12.5 pF that is a load capacitance CL of a crystal vibrator that has been used in the related art (refer to JP-A-2008-205658).

However, when the load capacitance CL is made to be small, a problem, which is related to a capacitance tolerance of the load capacitance CL and a frequency deviation Δf of an oscillation frequency, becomes significant. For example, in regard to safety Δf (ppm) of the oscillation frequency in a case where the load capacitance CL varies by ΔC (±5%) that is a range of a normal capacitance tolerance, when the load capacitance CL is 12.5 pF, the safety Δf of the oscillation frequency becomes 7.3 ppm at ΔC of 1.25 pF, when the load capacitance CL is 6 pF, the safety Δf of the oscillation frequency becomes 13.2 ppm at ΔC of 0.6 pF, and when the load capacitance CL is 3 pF, the safety Δf of the oscillation frequency becomes 20.5 ppm at ΔC of 0.3 pF.

That is, in the load capacitance CL (3 pF), the frequency deviation becomes 2.8 times larger compared to the case of 12.5 pF in the related art, such that to realize the low capacitance (low CL) of the load capacitance CL, it is necessary to improve safety of the oscillation frequency with respect to the capacitance tolerance of the load capacitance CL.

A crystal vibrator-side equivalent circuit between the input and output terminals XCIN and XCOUT in FIG. 12 corresponds to FIG. 13. A load capacitor CL is connected in series to the crystal vibrator X2, and the crystal vibrator is represented by a circuit in which an inter-electrode capacitor C0 is connected in parallel to a serial resonance circuit of an inductance L1, a capacitance C1, and a resistance R1, which equivalently represents a mechanical resonance generated by a piezoelectric effect. In addition, various kinds of stray capacitances are present between the input and output terminals XCIN and XCOUT due to a CMOS semiconductor substrate, a signal wiring, or the like, but when a (composite) stray capacitance thereof is set to a stray capacitance Cs, as shown in FIG. 14, the load capacitor CL is connected in parallel to an external (externally attached) capacitors Cg and Cd that are connected in series to the stray capacitor Cs. Therefore, a relational equation of CL=Cs+Cg*Cd/(Cg+Cd) is satisfied.

When externally attached capacitative elements Cg and Cd are selected in conformity with an oscillation frequency in such a manner that the load capacitance CL (2 to 6 pF) satisfying the above-described relationship (2) is obtained, it is possible to improve safety of the oscillation frequency. That is, the load capacitance CL is the sum of the stray capacitance Cs and an external capacitance Cext {=Cg*Cd/(Cg+Cd)}, such that when a value of the external capacitance Cext is set to correspond to a difference between the load capacitance CL and the stray capacitance Cs, the above-described equation is satisfied, and therefore it means that the load capacitance CL of the crystal vibrator and the load capacitance CL at the oscillation circuit side seen from the crystal vibrator are matched.

FIG. 15 shows a diagram illustrating a relationship between a driving current and the load capacitance CL in the crystal oscillation circuit. From the relationship, it can be seen that as the load capacitance becomes small, the driving current decreases significantly. For example, the driving current of the load capacitance 12.5 pF that is used in the related art is substantially 1.5 μA, but the driving current of the load capacitance 2.2 pF becomes 0.073 μA, and therefore the driving current decreases to substantially 5%. In this manner, the decrease in the load capacitance CL may contribute to the lowering of the power consumption of the crystal oscillation circuit, and forcibly contribute greatly to the saving of power of an electronic apparatus that uses the crystal oscillation circuit.

To realize lower power consumption of a crystal oscillation circuit, it is extremely effective to reduce the load capacitance. From the above-described equation, it can be seen that as the stray capacitance Cs becomes large, the load capacitance CL also becomes large. Therefore, to realize a small load capacitance CL, it is necessary to make the stray capacitance Cs small. The stray capacitance Cs is a composite stray capacitance generated by a CMOS semiconductor substrate, a signal wiring, or the like, and for example, varies depending on the lamination number of mounting substrates. The stray capacitance Cs is substantially 1 pF in a single-layer substrate, substantially 2 pF in a two-layer substrate, and substantially 3 pF in a three-layer substrate. However, a method of stably realizing this small load capacitance, or a specific method of mounting an oscillation circuit in the mounting substrate to make this stray capacitance Cs small has not been established.

### SUMMARY OF THE INVENTION

An object of the present invention is to provide a means for reducing a stray capacitance Cs in a crystal oscillation circuit disposed in a mounting substrate. Specifically, according to an aspect of the invention, there is provided an oscillation circuit including a crystal vibrator that is connected between input and output terminals of a CMOS inverter making up the oscillation circuit; an input wiring line that includes a crystal vibrator-side input terminal connected to an input terminal pad of the CMOS inverter; an output wiring line that includes a crystal vibrator-side output terminal connected to an output terminal pad of the CMOS inverter; a ground power source wiring line that includes a crystal vibrator-side ground power source terminal; and a capacitative element that is connected between the input wiring line and the ground power source wiring line, and between the output wiring line and the ground power source wiring line, wherein the ground power source wiring line is disposed at least a part of between the input wiring line and the output wiring line.

An earth wiring line (ground power source wiring line) is disposed between input and output terminals and a wiring in the crystal oscillation circuit that is laid out in a mounting substrate, such that a stray capacitance Cos between input and output may be reduced, and thereby reduction in a total stray capacitance Cs may be realized, and as a result thereof, low power consumption of the crystal oscillation circuit may be realized.

### BRIEF DESCRIPTION OF THE DRAWINGS

FIGS. 1A and 1B are a schematic diagram illustrating a shield wire type according to the present invention, in which a ground power source wiring line is disposed between input and output wiring lines;

FIG. 2 is a diagram illustrating a layout of an oscillation circuit in the related art, in which a mounting substrate in which a crystal vibrator and two externally attached capacitative elements are disposed is schematically illustrated;

FIG. 3 is a diagram illustrating an embodiment of a layout of a mounting substrate that mounts an IC chip to which an externally attached crystal vibrator is provided by using the shield wire type of the invention;

FIG. 4 is a schematic diagram illustrating a modified embodiment of a mounting pattern in FIG. 3;

FIG. 5 is a diagram illustrating another modified embodiment of the embodiments shown in FIGS. 3 and 4;

FIG. 6 is a diagram illustrating an embodiment in which a pattern according to the shield wire type of the invention is schematically shown, in a case where an IC package, in which an IC chip having an embedded inverter for an oscillation circuit is mounted, is mounted in a mounting substrate, and a crystal vibrator and a load capacitor are mounted in a wiring pattern for the oscillation circuit, which is formed in the same mounting substrate;

FIG. 7 is a diagram illustrating an embodiment in which the embodiment shown in FIG. 6 is modified;

FIG. 8 is a diagram illustrating an embodiment of a mounting layout related to the shield wire type of the invention in a case where a ground power source pad is disposed between an input pad and output pad of an inverter for the oscillation circuit of the IC chip;

FIG. 9 is a diagram illustrating a modified embodiment of the embodiment shown in FIG. 8;

FIG. 10 is a diagram illustrating an embodiment in which a pattern according to the shield wire type of the invention is schematically shown, in a case where an IC package, in which an IC chip having an embedded inverter for an oscillation circuit is mounted, is mounted in a mounting substrate, and a crystal vibrator and a load capacitor are mounted in a wiring pattern for the oscillation circuit, which is formed in the same mounting substrate;

FIG. 11 is a diagram illustrating an embodiment in which the embodiment shown in FIG. 10 is modified;

FIG. 12 is a diagram illustrating an oscillation circuit using the crystal vibrator;

FIG. 13 is a diagram illustrating a crystal vibrator-side equivalent circuit between input and output terminals XCIN and XCOUT in FIG. 12;

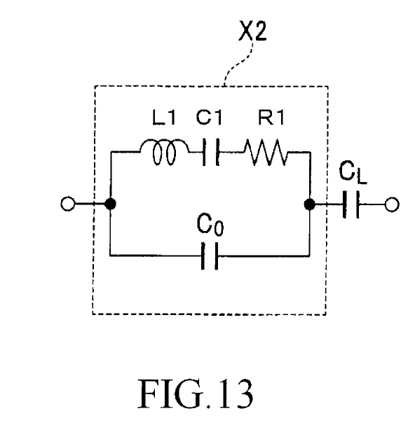

FIG. 14 is a diagram illustrating a capacitor making up the load capacitance CL;

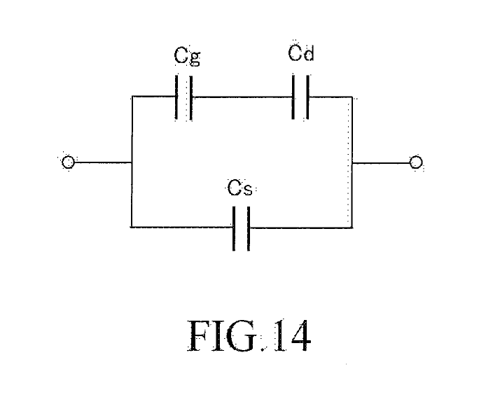

FIG. 15 is a diagram illustrating a relationship between a driving current and the load capacitance CL in a crystal oscillation circuit; and

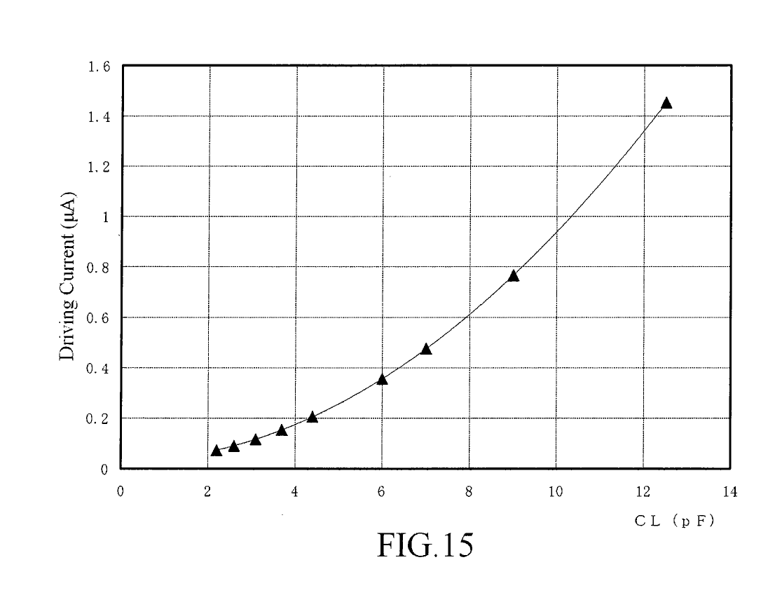

FIG. 16 is a table illustrating measured data of a stray capacitance and oscillation characteristics (an oscillation activation time and a negative resistance) in the shied wire type and a single wire type.

### DETAILED DESCRIPTION OF THE PREFERRED EMBODIMENTS

An object of the invention is to provide a means for reducing a stray capacitance Cs in a crystal oscillation circuit disposed in a mounting substrate, thereby reducing a load capacitance CL in a crystal oscillation circuit. Specifically, the stray capacitance Cs varies considerably due to a layout of a signal wiring line and a power source wiring line, such that the present inventors found that through various experiments, it is possible to largely reduce the stray capacitance Cs depending on a type of taking out an earth (ground), that is, ground potential (Vss) line. In addition, here, the crystal oscillation circuit represents an oscillation circuit using a crystal vibrator as a piezoelectric vibrator.

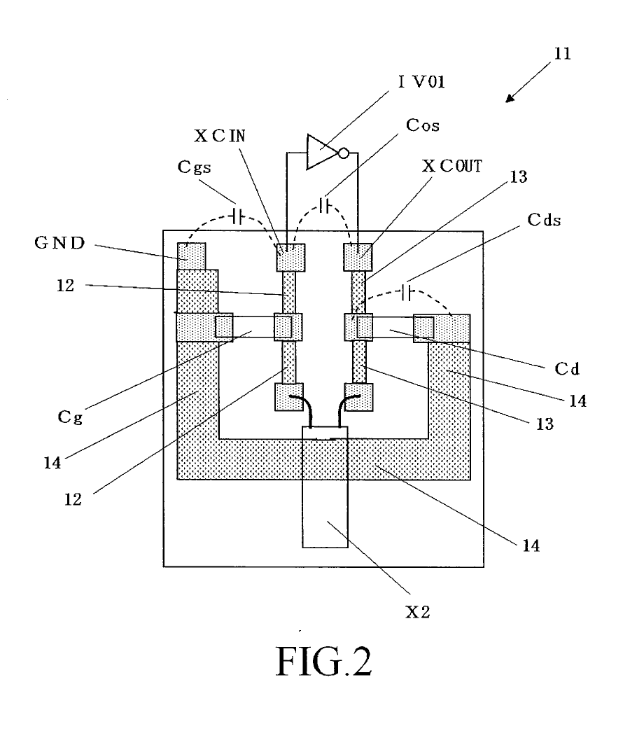

FIG. 2 shows a diagram illustrating a layout of an oscillation circuit in the related art, in which a mounting substrate in which a crystal vibrator X2 and two externally attached capacitative elements Cg and Cd are disposed is schematically illustrated. In this drawing, a stray capacitance is designated by a broken line. In a mounting substrate 11, an externally attached capacitative element Cg, an externally attached capacitative element Cd, and a crystal vibrator X2 are disposed. The externally attached capacitative element Cg is connected between an input terminal XCIN of a CMOS inverter IV01 and an input wiring line 12 (hereinafter, if not specifically described, the input wiring line includes an input terminal) connected thereto, and an earth (GND, a ground power source terminal Vss) and a ground power source wiring line 14 connected thereto (hereinafter, if not specifically described, the ground power source wiring line includes a ground power source terminal), the externally attached capacitative element Cd is connected between an output terminal XCOUT and an output wiring line 13 connected to thereto (hereinafter, if not specifically described, the output wiring line includes an output terminal), and the ground power source wiring line 14, and the crystal vibrator X2 is connected between the input wiring line 12 connected to the input terminal XCIN of the CMOS inverter IV01 and the output wiring line 13 connected to the output terminal XCOUT. In addition, a stray capacitance is present between the wiring lines disposed in the mounting substrate 11. That is, a stray capacitance Cgs is present between the input wiring line 12 and the ground power source wiring line, a stray capacitance Cds is present between the output wiring line 13 and the earth terminal (ground terminal) GND, and a stray capacitance Cos is present between the input wiring line 12 and the output wiring line 13. From these stray capacitances, a total stray capacitance Cs may be expressed by the following equation.

Cs=Cos+Cgs*Cds/(Cgs+Cds)

Therefore, from this equation, it can be seen that to reduce the stray capacitance Cs, it is effective to reduce the stray capacitance Cos.

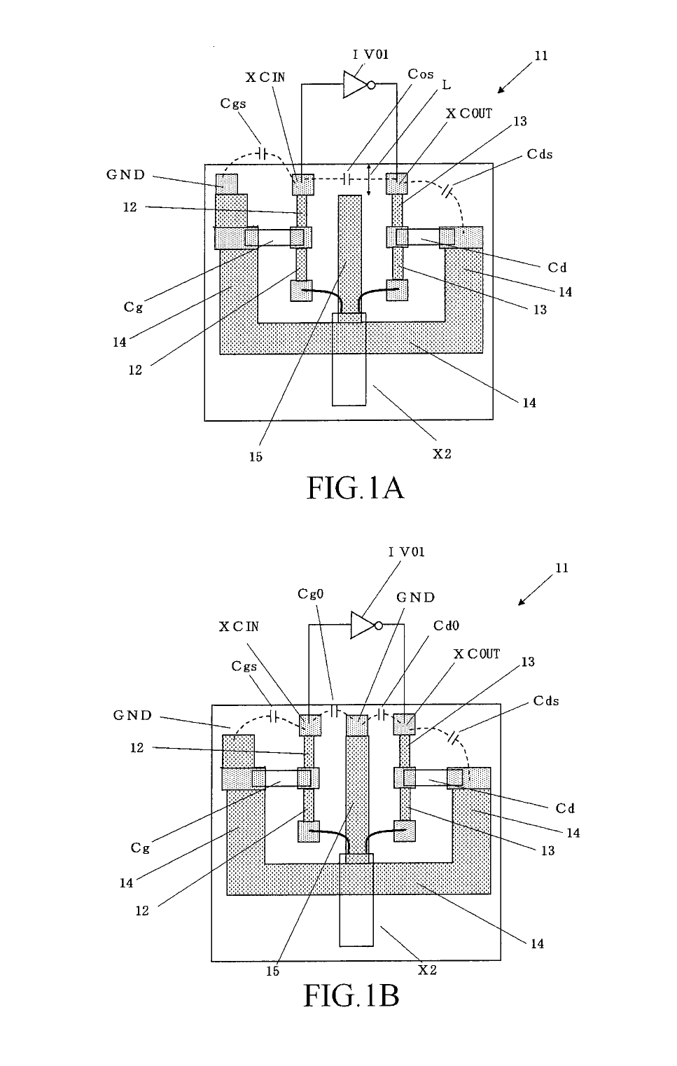

FIGS. 1A and 1B show a schematic diagram illustrating a shield wire type according to the present invention, in which a ground power source wiring line is disposed between input and output wiring lines, but as shown in FIG. 1A, a ground power source wiring line 15 is disposed between the input wiring line 12 and the output wiring line 13. The stray capacitance Cos may be made to approach zero by extending the ground power source wiring line 15 to an edge of the input terminal XCIN and the output terminal XCOUT of the substrate 11 to the maximum (that is, in such a manner that the distance L from an edge of the input terminal XCIN and the output terminal XCOUT of the substrate 11 to an edge of the ground power source wiring line 15 approaches zero). For example, as shown in FIG. 1B, when the ground power source terminal GND is disposed between the input terminal XCIN and the output terminal XCOUT, the stray capacitance Cos may be reduced (the stray capacitance Cos decreases significantly, and therefore approaches an ideal state (the stray capacitance Cos→0). As a result thereof, from the above-described equation, the following relationship is satisfied: the total stray capacitance Cs≅stray capacitance Cgs*externally added capacitance Cds/(stray capacitance Cgs+externally added capacitance Cds). From this, a value of the stray capacitance may be controlled by the externally attached capacitors Cg and Cd, and therefore, the lowering of CL may be realized. Specifically, a capacitance CG that is present between the input terminal XCIN and the earth terminal (ground terminal) GDN satisfies a relationship of CG=Cg+Cgs+Cg0, and a capacitance CD that is present between the output terminal XCOUT and the earth terminal (ground terminal) GND satisfies a relationship of CD=Cd+Cds+Cd0.

Hereinafter, an embodiment of the invention will be described in detail. In addition, a type of reducing the stray capacitance Cos by providing the ground power source wiring line between the input and output wiring lines of the invention is called a shield wire type.

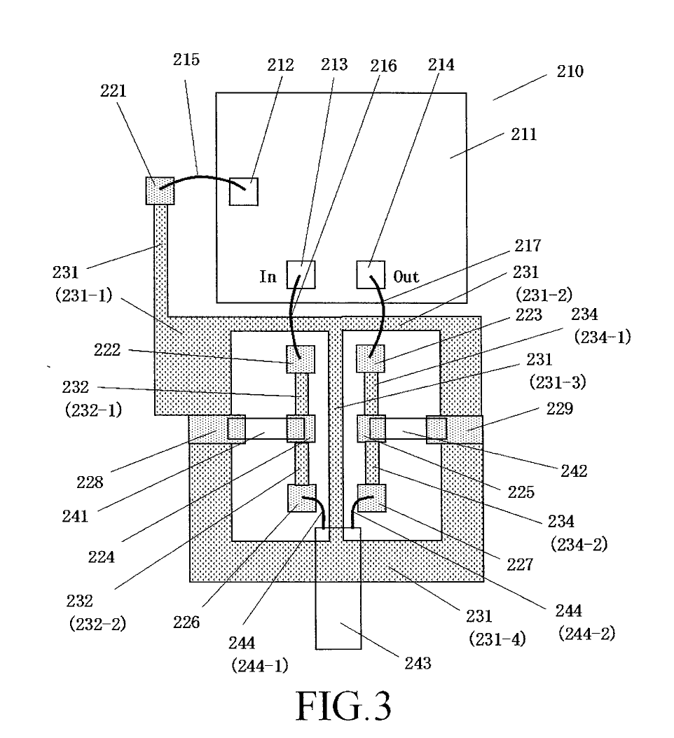

FIG. 3 shows a diagram illustrating an embodiment of a layout of a mounting substrate that mounts an IC chip to which an externally attached crystal vibrator is provided by using the shield wire type of the invention. The IC includes, for example, a microcomputer for a mobile telephone, a microcomputer for a camera control, or the like. An IC chip 211 in which an inverter for an oscillation circuit is embedded is mounted as a bare chip in a mounting substrate 210. As the mounting substrate, a printed substrate such as a rigid substrate and a flexible substrate may be exemplified. Furthermore, the IC chip 211 may be mounted on a lead frame, a ceramic substrate, or the above-described substrate and then may be packaged with a plastic molding. On the substrate, oscillation circuit wiring patterns 221, 222, 223, 224, 225, 226, 227, 228, 229, 231, 232, 234, or the like shown in the drawing are formed. The wiring patterns are formed by gold, silver, copper, aluminum, or an alloy of these, and are covered with an insulating film such as resist in a region except for parts such as a condenser and a region that is wire-bonded.

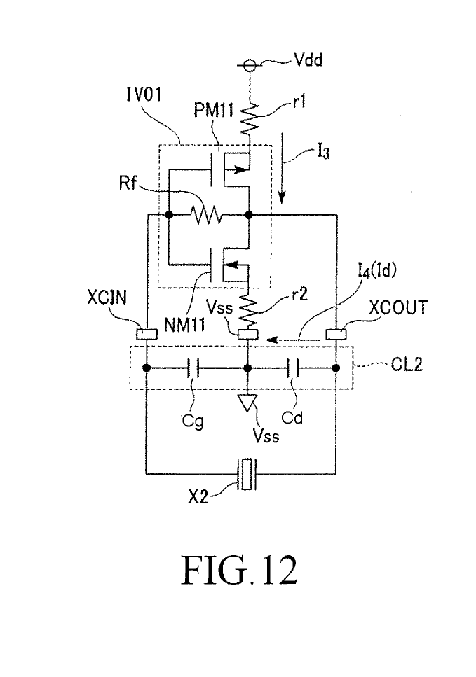

An input terminal (pad) 213 of an inverter for an oscillation circuit of the IC and an oscillation circuit-side input terminal (pad) 222 (designated by XCIN in FIGS. 1A and 1B) at the side of the substrate in which a crystal vibrator is mounted are connected by a metallic wire 216. In addition, an output terminal (pad) 214 of the inverter for the oscillation circuit of the IC and an oscillation circuit-side output terminal (pad) 223 (designated by XCOUT in FIGS. 1A and 1B) at the side of the substrate in which a crystal vibrator is mounted are connected by a metallic wire 217. The metallic wires 216 and 217 are formed of a conducting material such as copper, gold, and aluminum. Lead wiring lines 244 (244-1 and 244-2) are connected, respectively, between a crystal vibrator 243, and a wiring terminal (pad) 226 connected to input-side wiring lines 232 (232-1 and 232-2) of the mounting substrate, and a wiring terminal (pad) 227 connected to an output-side wiring lines 234 (234-1 and 234-2) of the mounting substrate. A ground power source terminal (pad) 212 of the IC chip 211 is connected to a substrate-side ground terminal (pad) 221 by a metallic wire 215 (designated by Vss in an oscillation circuit in FIG. 12). Substrate-side ground power source wiring lines are designated by 231 (231-1, 231-2, 231-3, 231-4, and 232-5). Electrodes of both ends of a load capacitor (condenser) 241 (designated by Cg in FIG. 12) are connected to a wiring terminal (pad) 224 that is a part of the input-side wiring lines 232 of the mounting substrate and a wiring terminal (pad) 228 that is a part of the ground power source wiring line 231, respectively. In addition, electrodes of both ends of a load capacitor (condenser) 242 (designated by Cd in FIG. 12) are connected to a wiring terminal (pad) 225 that is a part of the output-side wiring lines 234 of the mounting substrate and a wiring terminal (pad) 229 that is a part of the ground power source wiring line 231, respectively. In this manner, the bare chip 211, the load capacitors 241 and 242, and the crystal vibrator are mounted in the mounting substrate and make up an oscillation circuit section.

In the embodiment shown in FIG. 3, a wiring pattern of the ground power source wiring line 231 of the mounting substrate is schematically illustrated in regard to a case where the chip-side ground power source pad 212 is disposed at the outside of the input and output pads 213 and 214. Specifically, the ground power source wiring line 231 of the mounting substrate surrounds the mounting substrate-side input terminal 222, the input-side wiring lines 232 (232-1 and 232-2) connected thereto, and the wiring pads 224 and 226. Furthermore, the ground power source wiring line 231 surrounds the mounting substrate-side output terminal 223, the output-side wiring line 234 (234-1 and 234-2) connected thereto, and the wiring pad 225 and 227. More importantly, the ground power source wiring line 231 (231-3) is interposed between the input-side wiring lines (222, 232 (232-1 and 232-2), and the wiring pads 224 and 226) and the output-side wiring lines (223, 234 (234-1 and 234-2), and the wiring pads 225 and 227), at the side of the mounting substrate, and thereby separates these. Therefore, as described with reference to FIG. 1, the stray capacitance Cos becomes very small. However, in the case of FIG. 3, the ground power source wiring line is not provided between the IC-side input pad 213 and output pad 214, and furthermore, the ground power source wiring line is also not provided between the wires 216 and 217, such that it is still insufficient. In addition, a terminal pad not related to the description of the invention is not described in regard to the IC chip, but a terminal pad that is connected to another part or a wiring line of the mounting substrate may be provided at an arbitrary position of the IC chip.

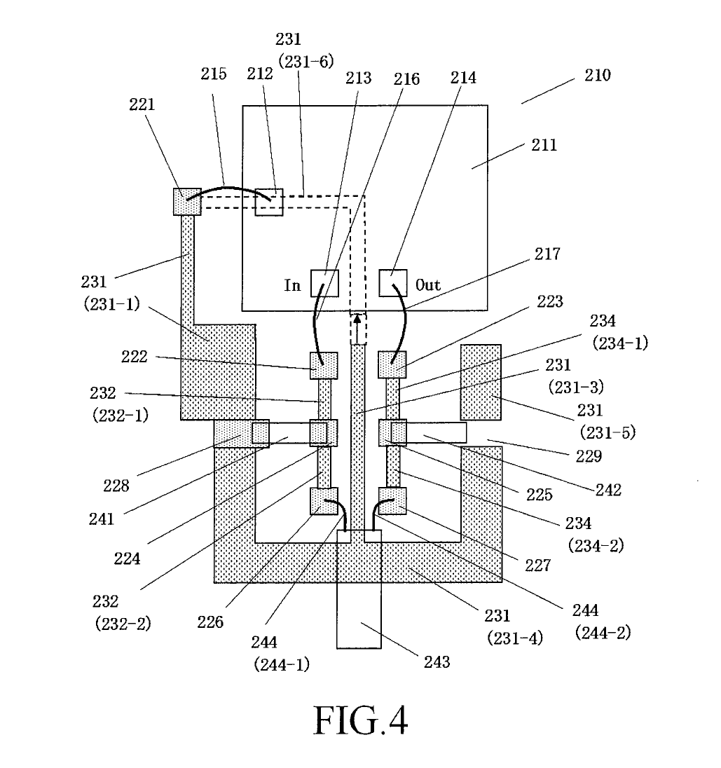

FIG. 4 shows a schematic diagram illustrating a modified embodiment of the pattern in FIG. 3. This embodiment illustrates a case where the ground power source wiring line is not provided between the input and output terminals 213 and 214 of the IC chip, and the substrate-side input and output terminals 222 and 223. (That is, a case where the ground power source wiring line 231-2 is not provided in FIG. 3). For example, between a location at which the IC chip is placed and the substrate-side input and output terminals 222 and 223 become short, and therefore, there may occur a case where it is difficult to form the ground power source wiring line 231-2, or a case where noise or the like occurs because the metallic wires 216 and 217 are formed to extend across the ground power source wiring line 231-2, or particularly, a case where the metallic wires approach each other and thereby a problem occurs (however, commonly, the metallic wires are covered with a resist or the like that is an insulating film, such that even when the wires come into contact with each other, a problem such as conduction occurs rarely), or the like. Even when such a ground power source wiring line 231-2 is not provided, as shown in FIG. 4, due to the ground power source wiring line 231 (231-1, 231-4, and 231-5) that surrounds the substrate-side input wiring line 232 or the like and the output wiring line 234 or the like from the outside, the ground power source wiring line 231 (231-3) is interposed between the input-side wiring lines (222, 232 (232-1 and 232-2) and the wiring pads 224 and 226), and the output-side wiring lines (223, 234 (234-1 and 234-2) and the wiring pads 225 and 227), at the side of the mounting substrate, to separate these to the maximum, and more preferably, the ground power source wiring line 231 (231-3) is extended to completely separate the input pad 222 and the output pad 223. As indicated by an arrow and a dotted line, the ground power source wiring line 231 (231-3) is arranged as close as possible to the IC chip 211. Furthermore, in a case where a problem does not occur even when the ground power source wiring line 231 overlaps the IC chip, as indicated by the dotted line, when a ground power source wiring line 231-6 is formed under the IC chip and thereby passes between the input pad 213 and the output pad 214 of the IC chip 211, resulting in an even better effect.

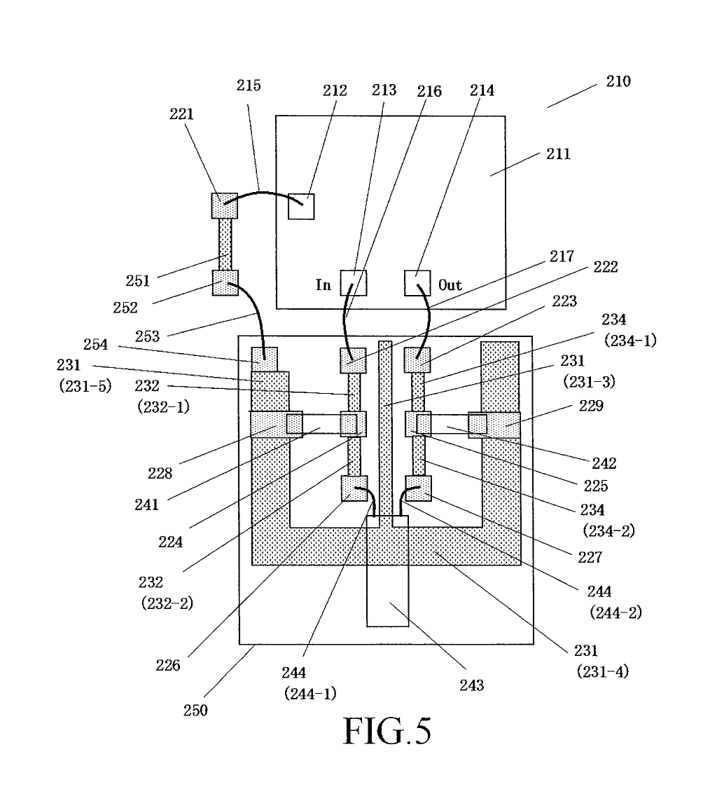

FIG. 5 shows a new modified embodiment of the embodiment shown in FIGS. 3 and 4. An arrangement of the input and output pads and the ground power source pad of the IC is the same as that shown in FIGS. 3 and 4, the IC chip 211 is mounted in the mounting substrate 210. A wiring pattern of a crystal vibrator-side oscillation circuit is formed on a separate substrate 250, and the crystal vibrator 243 and the load capacitors 241 and 242 are mounted on the separate substrate 250. The wiring pattern of the crystal vibrator-side oscillation circuit is the same as the case shown in FIG. 4, but the ground power source wiring line 231 is connected to a ground power source terminal (pad) 254. The separate substrate 250 may be mounted on the mounting substrate 210 similarly to the IC chip (through a bonding or the like) (or, may be located separately from each other). The mounting substrate 210 has the ground power source terminal (pad) 221 and this ground power source pad 221 and the ground power source pad 212 of the IC are connected by the metallic wire 215. The mounting substrate 210 further has a ground power source wiring line 251 that is connected to the ground power source pad 221, and a ground power source pad 252. The ground power source pad 252 and the ground power source pad 254 on the separate substrate 250 are connected by a metallic wire. As a result thereof, the ground power source pad of the IC chip 211 has the same potential as a ground potential of the ground power source wiring line of the separate substrate 250 on which the crystal vibrator is mounted and the mounting substrate 210. In the separate substrate 250, the ground power source wiring line 231 (231-3) separates the input wiring line 232 or the like, and the output wiring line 234 or the like of the crystal vibrator-side oscillation circuit, such that the stray capacitance Cos is reduced. As described above, when the crystal vibrator-side oscillation circuit is formed in the separate substrate 250, even when a special wiring pattern of an oscillation circuit is not formed in the mounting substrate 210, it is possible to arrange an oscillation circuit having a function as an IC on the mounting substrate by being combined with the IC chip. In addition, the ground power source wiring line 231 of the separate substrate is made as a wiring pattern as shown in FIG. 3 to surround the input and output pads 222 and 223. Furthermore, the ground power source pad 254 of the separate substrate and the ground power source pad 212 of the IC may be directly connected by a metallic wire.

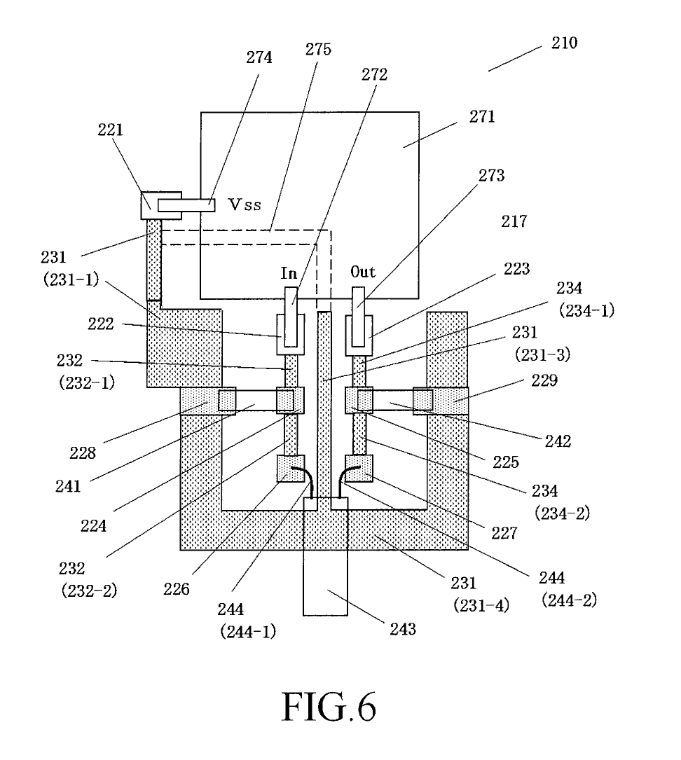

FIG. 6 shows a diagram illustrating an embodiment in which a pattern according to the shield wire type of the invention is schematically shown, in a case where an IC package 271, in which an IC chip having an embedded inverter for the oscillation circuit is mounted, is mounted in a mounting substrate 210, and a crystal vibrator and a load capacitor are mounted in a wiring pattern for an oscillation circuit, which is formed in the same mounting substrate 210. An input lead terminal 272 and an output lead terminal 273 of the inverter for the oscillation circuit of the IC package 271, and a ground power source lead terminal 274, which is located at an external side of these are connected to the input terminal (pad) 222, the output terminal (pad) 223, and the ground power source terminal (pad) 221 of the crystal vibrator-side oscillation circuit pattern in the substrate 210, respectively. A connection method includes a method of soldering a lead (conducting wire) of the IC package 271 to a wiring line pad of the mounting substrate, a method of bonding the lead to the wiring line pad using a conductive adhesive, or the like. The IC package includes various plastic packages including a lead line type such as QFP, SOP, SOJ, QFJ, and PLCC, a non-lead type such as QFN, SON, and LLCC, a ball terminal type such as BGA and CSP, a planar electrode type such as LGA, a tape type such as TCP, and an insertion type such as DIP, various ceramic packages, or the like. As a mounting (terminal connecting) method to the mounting substrate, a method conforming with the respective packages may be used.

In a case where a wiring line of the mounting substrate 210 is single layer type, it is difficult to form the ground power source wiring line 231-2 shown in FIG. 3 between the IC package 271 and the input and output terminals 222 and 223 of the crystal vibrator-side oscillation circuit shown in FIG. 6, such that the ground power source wiring line 231-3, which is branched from the ground power source wiring line 231 (231-4) surrounding the mounting substrate-side oscillation circuit pattern, is provided between the input wiring line 232 or the like and the output wiring line 234 or the like and is made to separate these input and output wiring lines. As shown in FIG. 6, the ground power source wiring line 231-3 is disposed as close as possible to the IC package. When there is no problem related to a function of the IC, an oscillation characteristic, or a connection of the terminal pad, a ground power source wiring line 275 indicated by a dotted line may be provided immediately under a region on which the IC chip is mounted. In this manner, Cos may be further reduced.

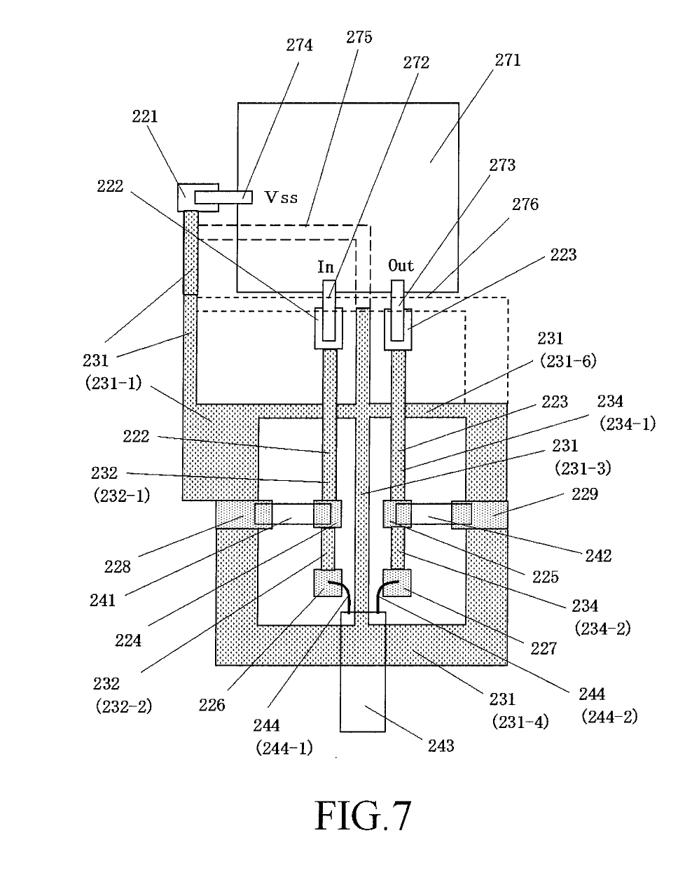

FIG. 7 shows a diagram illustrating an embodiment in which the embodiment shown in FIG. 6 is modified. In FIG. 7, a relationship between the input and output lead terminals 272 and 273, and the ground power source lead terminal 274 of the IC package 271 is the same as that shown in FIG. 6. However, as the mounting substrate 210, a substrate in which a wiring line may be formed in two layers is used in FIG. 7. Therefore, wiring patterns in the mounting substrate may be intersected. For example, a ground power source wiring line 276 may be provided immediately under the lead lines 272 and 273, and may surround the input and output wiring lines. In addition, as shown in FIG. 6, the ground power source wiring line 275 may be provided under the IC chip 271. In this manner, the stray capacitance Cos may be further reduced. In this case, the ground power source wiring line 276 and another ground power source wiring line may be different in a wiring layer, but these two upper and lower ground power source wiring lines may be connected by a through-hole. In addition, a ground power source wiring line 231 (231-6) may be formed to be intersected with the input wiring line 232 (232-1) and the output wiring line 234 (234-1). In this manner, the oscillation circuit in the mounting substrate is surrounded by the ground power source wiring lines 231, 275 or 276, such that the stray capacitance Cos may be further reduced.

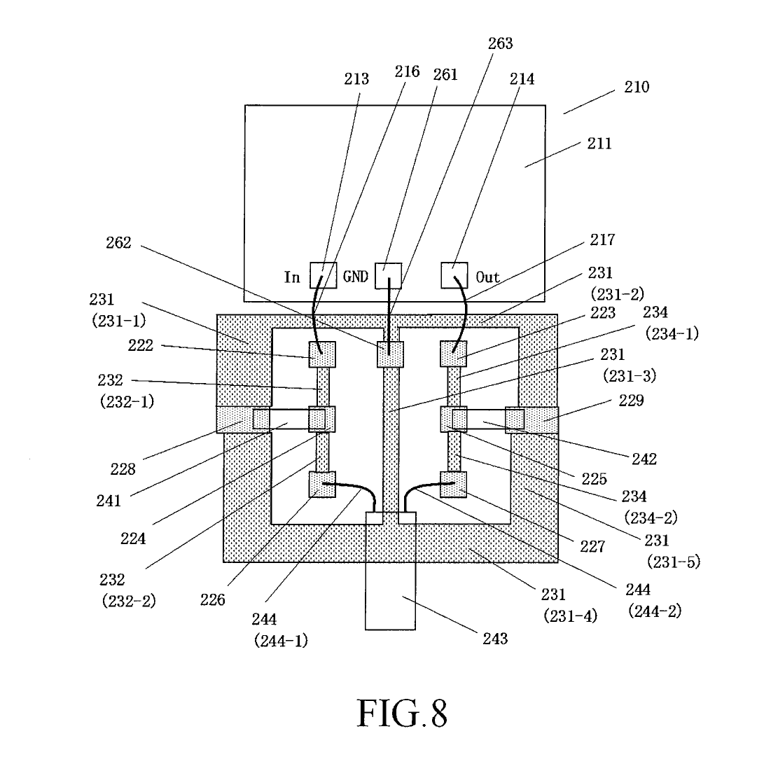

FIG. 8 shows a diagram illustrating an embodiment of a mounting layout related to the shield wire type of the invention in a case where a ground power source terminal (pad) is disposed between the input terminal (pad) and output terminal (pad) of the inverter for the oscillation circuit of the IC chip. The ground power source pad 261 is disposed between the input pad 213 and the output pad 214 of the inverter for the oscillation circuit of the IC chip 211. This IC chip 211 is mounted as a bare chip in the mounting substrate 210. With respect to this, a layout of the crystal vibrator-side oscillation circuit pattern wiring line is formed. A ground power source terminal (pad) 262 is disposed between the crystal vibrator-side input terminal (pad) 222 and the output terminal (pad) 223. The input pad 213, the output pad 214, and the ground power source pad 261 of the IC chip 211 is conductively connected to the crystal vibrator-side input terminal (pad) 222, the output terminal (pad) 223, and the ground power source terminal (pad) 262 on the mounting substrate, respectively, through metallic wires 216, 217, and 263. These metallic wires are bonded to respective terminals (pads) through a wire bonding method. In FIG. 8, the ground power source wiring lines 231 (231-1, 231-2, 231-4, and 231-5), 228, and 229 are connected to the ground power source terminal (pad) 262, and thereby completely surround the wiring lines 232 (232-1 and 232-2), 224, 225, and 234 (234-1 and 234-2), and the load capacitors 241 and 242 for the substrate-side oscillation circuit, and the crystal vibrator 243. In addition, the ground power source wiring line 231 (231-3) connected to the ground power source pad 262 is provided between the input wiring line 232 and the output wiring line 234 and thereby completely separates these. Therefore, the reduction of the stray capacitance Cos may be realized. To further reduce the stray capacitance Cos, it is preferable to arrange the IC chip 211 as close as possible to the input and output pads 222 and 223, and the ground power source pad 262 of the mounting substrate. Furthermore, the length of the metallic wires 216, 217, and 262 may be shortened.

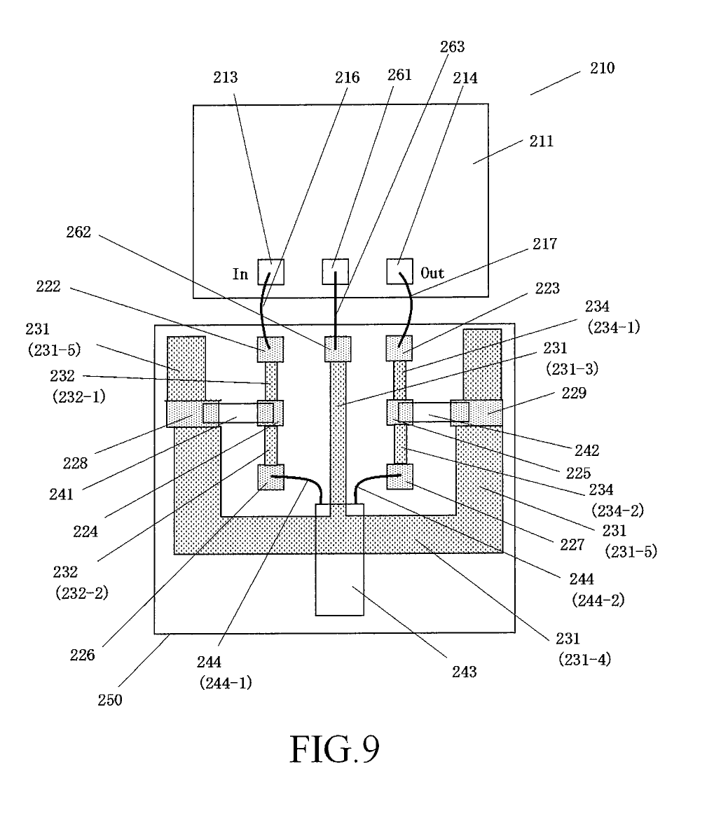

FIG. 9 shows a modified embodiment of the embodiment shown in FIG. 8. Specifically, the crystal vibrator-side oscillation circuit is layout-wired in a separate substrate 250, and the crystal vibrator 243 and the load capacitors 241 and 242 are mounted in the separate substrate 250. This separate substrate 250 is disposed in the mounting substrate 210 through a bonding or the like in conformity with a pad arrangement of the IC chip 211. In this case, the input pad 213, the output pad 214, and the ground power source pad 261 of the IC chip 211 are conductively connected to the crystal vibrator-side input terminal (pad) 222, the output terminal (pad) 223, and the ground power source terminal (pad) 262 of the separator substrate fixed on the mounting substrate, through metallic wires 216, 217, and 263, respectively. In the separate substrate 250 shown in FIG. 9, the ground power source wiring lines 231 does not completely surround the input wiring line 232 or the like and the output wiring line 234 or the like (the wiring line 231 (231-2) in FIG. 8 is not provided), but the ground power source wiring line 231 (231-3) connected to the ground power source pad 262 is completely provided between the input wiring line 232 and the output wiring line 234 and completely separates these wiring lines, such that the reduction in the stray capacitance Cos may be realized. In a case where the size of the separate substrate 250 may be large, as shown in FIG. 8, the ground power source wiring line 231 (231-2) may be formed to completely surround the entirety of the input and output wiring lines 232 and 234 or the like. The present embodiment is characterized in that the layout-wiring necessary for the oscillation circuit may not be performed in the mounting substrate 210. By only opening a space in which the separate substrate 250 is mounted, it is possible to select various oscillation circuits that can obtain predetermined oscillation characteristics. For example, to realize further low power-consumption, it is easy to substitute the separate substrate with a crystal vibrator-side separate substrate in which CL is lowered. In addition, the combination with another IC chip may be realized. In addition, in a case where there is no space for providing the ground power source wiring line 231 (231-2) even in the case shown in FIG. 8, or in a case where when the ground power source wiring line 231 (231-2) is provided and this causes a problem (has an effect on oscillation characteristics, characteristics of IC, or the like), it is not necessary to layout-wire the ground power source wiring line 231 (231-2).

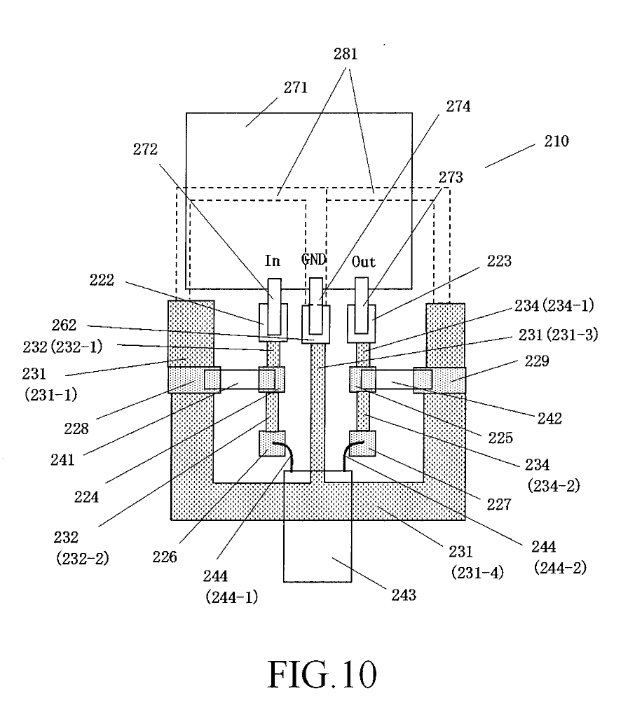

FIG. 10 shows a diagram illustrating an embodiment in which a pattern according to the shield wire type of the invention is schematically shown, in a case where an IC package 271, in which an IC chip having an embedded inverter for an oscillation circuit is mounted, is mounted in a mounting substrate 210, and a crystal vibrator and a load capacitor are mounted in a wiring pattern for the oscillation circuit, which is formed in the same mounting substrate 210, similarly to FIG. 6. The ground power source lead terminal 274 is provided between the input lead terminal 272 and the output lead terminal 273 of the inverter for the oscillation circuit of the IC package 271. Therefore, when the ground power source terminal (pad) 262 is disposed between the input terminal (pad) 222 and the output terminal (pad) 223 of the crystal vibrator-side oscillation circuit pattern in the substrate 210, as shown in FIG. 10, it is possible to directly connect the lead terminal 274 of the IC package to the ground power source terminal (pad) 262 of the mounting substrate. In addition, the input lead terminal 272 and the output lead terminal 273 are directly connected to the input terminal pad 222 and the output terminal pad 223 of the substrate 210. In addition, in regard to the integrated circuit (IC) mounted in the IC package, it is preferable that a ground power source terminal pad be disposed between the input terminal pad and the output terminal pad of the CMOS inverter making up the oscillation circuit. Furthermore, the input terminal pad, output terminal pad, and ground power source terminal pad of the CMOS inverter are connected to the input lead terminal 272, the output lead terminal 273, and the ground power source lead terminal 274 of the IC package, respectively.

In a case where the wiring line of the mounting substrate is a single layer type, the ground power source pad 262 may be also formed between the IC package 271, and the input and output terminals 222 and 223 of the crystal vibrator-side oscillation circuit. In addition, the ground power source wiring line 231-3 connected to the ground power source pad 262 may be also provided between the input wiring line 232 (232-1 and 232-2) and the output wiring line 234 (234-1 and 234-2). As a result, the input pad wiring lines (222, 232, and 224) and the output pad wiring lines (223, 234, 225) may be completely separated from each other by the ground power source pad wiring line (262 and 231-3). Furthermore, the IC-side input wiring line (the lead terminal 272 and the wiring line connected thereto) and output wiring line (the lead terminal 273 and the wiring line connected thereto) are also separated by the ground power source wiring line (the lead terminal 274 and the wiring line connected thereto). As a result, the stray capacitance Cos may be very small and close to zero.

In a case where the wiring line of the mounting substrate 210 is a single layer type, the ground power source wiring line 231-2 shown in FIG. 3 may not be formed, but as shown in FIG. 10, the ground power source wiring lines 231 (231-1, 231-3, and 231-4) may be formed to surround three sides of the input and output wiring lines. In addition, in a case where the wiring line of the mounting substrate 210 is a single layer type, as indicated by a dotted line 281, when the ground power source wiring line is formed under the IC package 271, the entirety of the input and output wiring lines may be surrounded by the ground power source wiring lines.

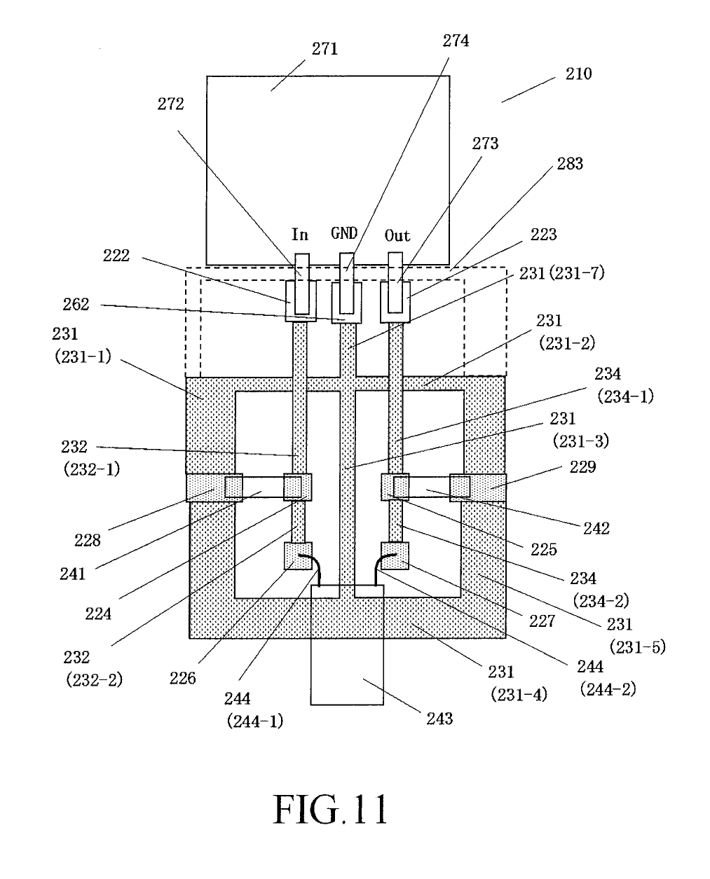

FIG. 11 shows an embodiment in which the embodiment shown in FIG. 10 is modified. FIG. 11 illustrates a case where the wiring line of the mounting substrate 210 may be two or more layers. In FIG. 11, the ground power source wiring lines 231 (231-1, 231-2, 231-3, 231-4, 231-5, and 231-7) are formed at a lower layer of the mounting substrate wiring line, and the input and output wiring lines 232 or the like and 234 or the like are formed at an upper layer. However, the input and output wiring lines are surrounded by the ground power source wiring lines 231 (231-1, 231-2, 231-3, 231-4, and 231-5), and the input and output wiring lines are separated from each other by the ground power source wiring lines 262, and 231 (231-3 and 231-7), such that the reduction in the stray capacitance Cos may be realized. In addition, a ground power source wiring line 283 indicated by a broken line may be disposed under the lead terminals (272, 273, and 274) or the IC package 271, such that the stray capacitance Cos may be further reduced.

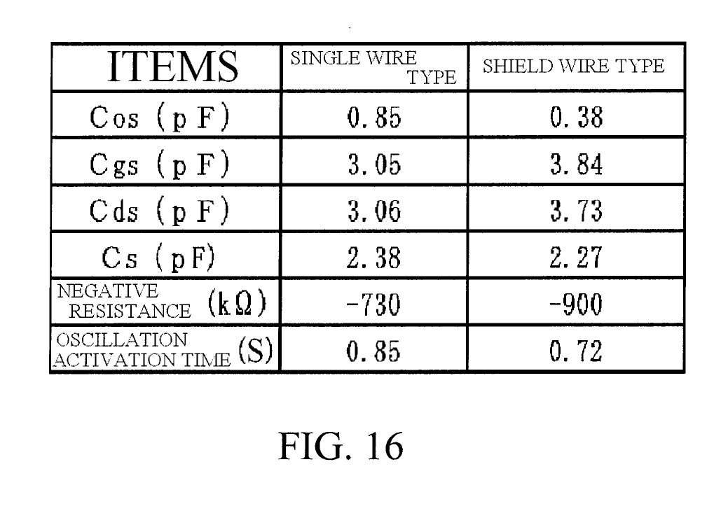

On a substrate having a pattern of a type in which the ground wiring line 14 surrounds the input terminal XCIN and the wiring line 12 connected thereto, and the output terminal XCOUT and the wiring line 13 connected thereto (referred to as a single wire type), as shown in FIG. 2, and a type in which the ground wiring line 15 surrounds the input terminal XCIN and the wiring line 12 connected thereto and the output terminal XCOUT and the wiring line 13 connected thereto, and the earth wiring line (ground power source wiring line) 15 is disposed between the wiring 12 connected to the input terminal XCIN and the wiring line 13 connected to the output terminal XCOUT (shield wire type) as shown in FIG. 1, a crystal vibrator having CL of 3.7 pF, and load capacitors having Cg of 3 pF, and Cd of 2 pF were mounted, and then a stray capacitance and oscillation characteristics (an oscillation activation time and a negative resistance) were measured. Results thereof were shown in FIG. 16. From the table in FIG. 16, it can be seen that the stray capacitance Cos of 0.85 pF in a single wire type becomes the stray capacitance Cos of 0.38 pF in a shield wire type, such that the stray capacitance Cos is largely reduced in the shield wire type. The stray capacitance Cgs and the externally added capacitance Cds increase a little, but this may be controlled by adjusting the externally attached capacitors Cg and Cd, such that the lowering of CL may be realized. In addition, the oscillation activation time may be shortened (approximately 15%) by the shield wire type, and as a result thereof, a gain of oscillation may be improved by substantially 25% compared to the single wire type.

As described above, in the present invention, (1) a ground power source wiring line (earth line or ground line) is provided between the input terminal XCIN and the output terminal XCOUT, and/or between the wiring line (input wiring line) connected to the input terminal XCIN and the wiring line (output wiring line) connected to the output terminal XCOUT to shield these. (2) between the input terminal XCIN and the output terminal XCOUT, and/or the entirety of the wiring line connected to the input terminal XCIN and the wiring line connected to the output terminal XCOUT is surrounded by the ground power source wiring line. (3) an earth terminal (ground terminal, earth terminal, Vss terminal) is provided between the input terminal XCIN and the output terminal XCOUT, and between the wiring line (input wiring line) connected to the input terminal XCIN, and the wiring line (output wiring line) connected to the output terminal XCOUT is shielded by a ground power source wiring line connected to the earth terminal in a sandwich type. In this manner, the stray capacitance Cos is reduced, and thereby the lowering of CL may be realized, and as a result thereof, power consumption may be reduced.

In addition, the above-described shield wire type is effective for enhancing a noise resistance and improving the oscillation performance, in addition to the reduction in the stray capacitance Cos between the input and output terminals and between the wiring lines. As shown in FIG. 16, by performing the shielding, a negative resistance RL becomes large, and as a result thereof, the oscillation gain is improved by substantially 25%. Furthermore, as shown in FIG. 16, by performing the shielding, the oscillation activation time is shortened substantially by 15%, and as a result thereof, the oscillation performance is improved. In addition, to improve the above-described shield wire type, an electrode area may be made to be small, and therefore a distance between terminals (a distance between the input terminal XCIN and the output terminal XCOUT, or a distance between wiring lines connected to the input and output terminals) may be made to be large, or a material having a small specific dielectric constant may be used for the substrate, this may be effective for the lowering of CL.

In addition, in the above description, an oscillation circuit using a crystal vibrator is mainly described, but even in a case where another piezoelectric vibrator (for example, a ceramic vibrator) or the like is used instead of using the crystal vibrator, the shield wire type of the present invention may be applied thereto.

The above-described oscillation circuit of the invention may be mounted and applied to an oscillation circuit that is used for an oscillator or an electronic apparatus using the crystal vibrator or another piezoelectric vibrator. For example, a battery driving type electronic apparatus such as a timepiece, a cellular phone, a portable terminal, and a notebook PC may be exemplified. In addition, the oscillation circuit may be applied to various kinds of electronic apparatuses such as in-vehicle electronic apparatuses and household electric appliances, which includes a television, a refrigerator, an air conditioner, or the like, in which saving of energy or saving of power is required.

The present invention may be used for an oscillation circuit using a crystal vibrator as a piezoelectric vibrator. Particularly, the invention is effective for realizing low power-consumption. In addition, the present invention may be used for an oscillator, an electronic apparatus, or the like, in which the oscillation circuit using the crystal vibrator is mounted.

What is claimed is:

1. An oscillation circuit comprising:
a crystal vibrator having an input terminal and an output terminal;
an electrical circuit comprising an inverter which is electrically connected between the input and output terminals of the crystal vibrator, wherein the electrical circuit comprise an input terminal, an output terminal and a ground terminal;
an input wiring and an output wiring extensive between the crystal vibrator and the electrical circuit to electrically connect the crystal vibrator and the inverter, wherein the input and output wirings have a first input end and a first output end connected, respectively, to the input and output terminals of the crystal vibrator and a second input end and a second output end connectible, respectively, to the input and second terminals of the electrical circuit; and
a ground wiring that defines a reference voltage level and is electrically connected to the ground terminal of the electrical circuit, wherein the ground wiring has an extension running between the input and output wirings to substantially segregate one from the other.

2. The oscillation circuit according to claim 1, wherein the ground wiring further runs in a shape of a closed loop to encompass the input and output wirings.

3. The oscillation circuit according to claim 1, wherein the ground wiring further runs in a shape of the letter “C” to surround the input and output wirings.

4. The oscillation circuit according to claim 1, wherein the extension of ground wiring has a terminal end connected to the ground terminal of the electrical circuit.

5. The oscillation circuit according to claim 1, wherein the ground wiring has a terminal end connected to the ground terminal of the inverter and located such that one of the first and second wirings is located between the terminal end of the ground wiring and the other of the first and second wirings.

6. The oscillation circuit according to claim 1, wherein the extension of the ground wiring extends to connect directly to the ground terminal of the electrical circuit.

7. The oscillation circuit according to claim 1, wherein the ground wiring runs on both sides of the oscillation circuit.

8. The oscillation circuit according to claim 7, wherein the ground wiring runs in a shape of the letter “C” on each side of the oscillation circuit to form a closed loop in combination.

9. The oscillation circuit according to claim 7, wherein the ground wiring runs in a shape of a closed loop on one side of the oscillation circuit.

10. The oscillation circuit according to claim 1, wherein the electrical circuit is contained in an IC chip comprising the inverter.

11. The oscillation circuit according to claim 1, wherein the electrical circuit is contained in an IC package comprising the inverter.

12. The oscillation circuit according to claim 1, wherein the oscillation circuit comprises a double-layered substrate.

13. An electronic device comprising the oscillation circuit according to claim 1.
